(19) United States
(12) Patent Application Publication
(10) Pub. No.: US 2014/0146492 A1
(43) Pub. Date: May 29, 2014

(54) POWER SUPPLY UNIT

(71) Applicants: HONG FU JIN PRECISION INDUSTRY (ShenZhen) CO., LTD., (US); HON HAI PRECISION INDUSTRY CO., LTD., New Taipei (TW)

(72) Inventor: Xian-Xiu TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/707,609

(22) Filed: Dec. 7, 2012

(30) Foreign Application Priority Data
Nov. 23, 2012 (CN) 2012104806588

(51) Int. Cl. H05K 5/02

(52) U.S. Cl. CPC H05K 5/0247
USPC 361/752

(57) ABSTRACT

A power supply unit includes an enclosure, a circuit board, a power interface, and a cable. The enclosure defines an opening in an end of the enclosure. The circuit board is mounted in the enclosure. The power interface is electrically connected to the circuit board, near the opening, to output DC voltages. The power interface includes a number of first pins facing the opening. The cable includes a plug at an end of the cable. The first pins of the power interface are detachably plugged into the plug.

### BACKGROUND

1. Technical Field

The present disclosure relates to a power supply unit.

2. Description of Related Art

Power supplies in servers are generally of the same size, although different servers have different sizes. The positions of motherboards and hard disk drives within different servers may be located differently. Thus, the lengths of the power cables of the power supplies need to be individually changed to suit. However, the power cables of the power supplies are generally soldered to circuit boards of the power supplies, which makes it hard to change the lengths of the power cables.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a power supply unit.

FIG. 2 is a partially enlarged view of the power supply unit of FIG. 1, but viewed from another perspective.

FIG. 3 is an assembled, isometric view of the power supply unit of FIG. 1.

FIG. 4 is similar to FIG. 3, but showing a different state of use.

FIG. 5 shows the power supply unit of FIG. 3 mounted in an electronic device.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one.”

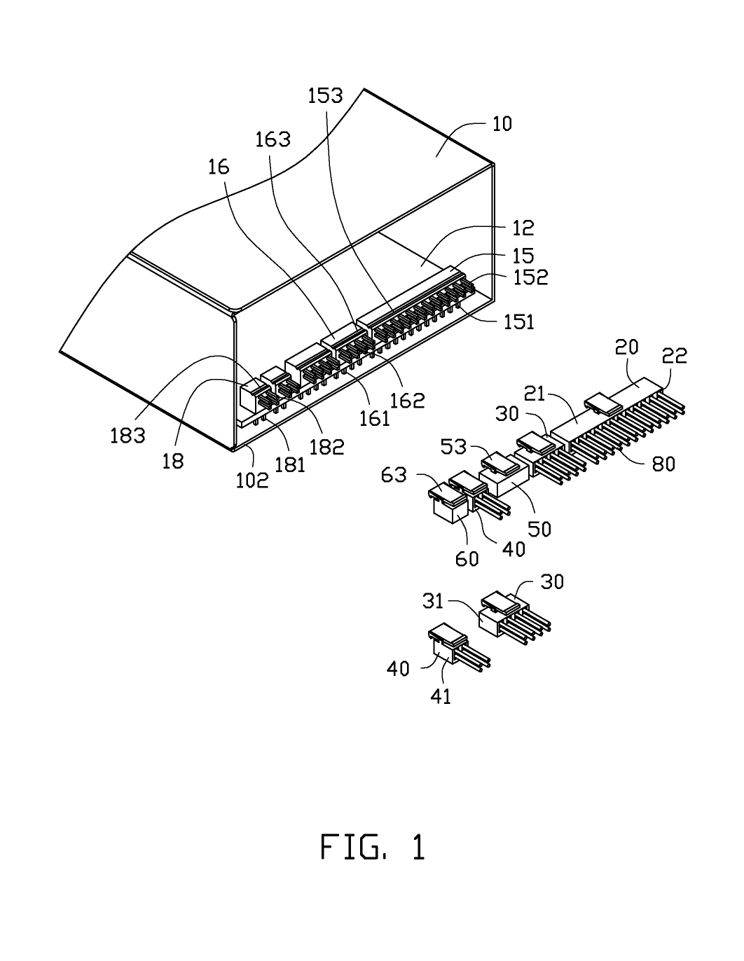

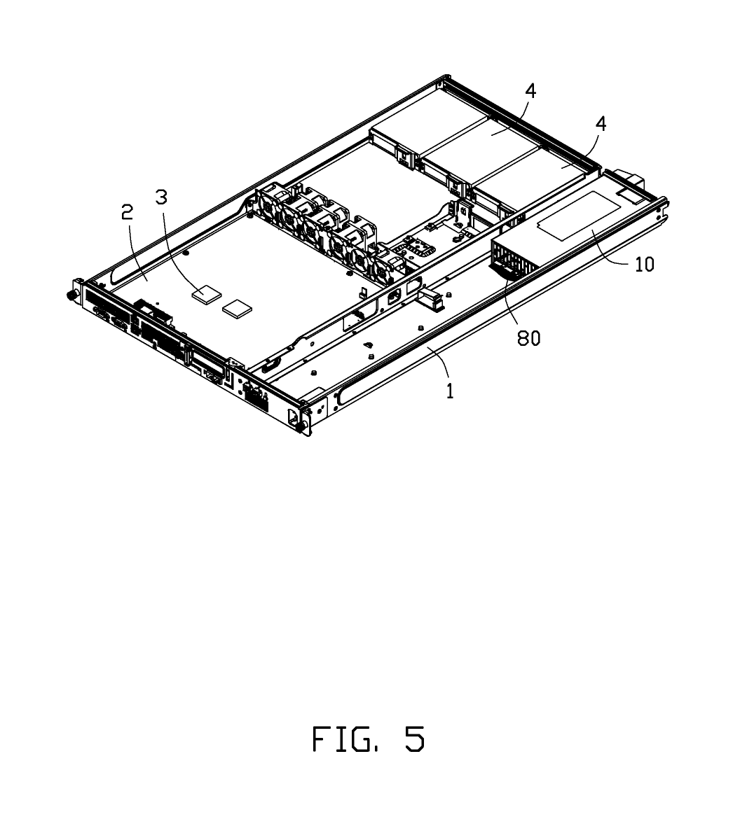

FIGS. 1 and 5 show an exemplary embodiment of a power supply unit provided for supplying power for electronic components of an electronic device 1. In the embodiment, the electronic device 1 is a server, the electronic components includes a motherboard 2, central processing units (CPUs) 3, and a plurality of hard disk drives (HDDs) 4. The power supply unit includes an enclosure 10, a circuit board 12 mounted on a bottom plate 102 of the enclosure 10 to convert commercial power (alternating current) into several direct current (DC) powers with different voltages, a first power cable 20, two second power cables 30, two third power cables 40, a first foolproof member 50, and a second foolproof member 60. Each of the first power cable 20, the second power cables 30, and the third power cables 40 can be set with different lengths.

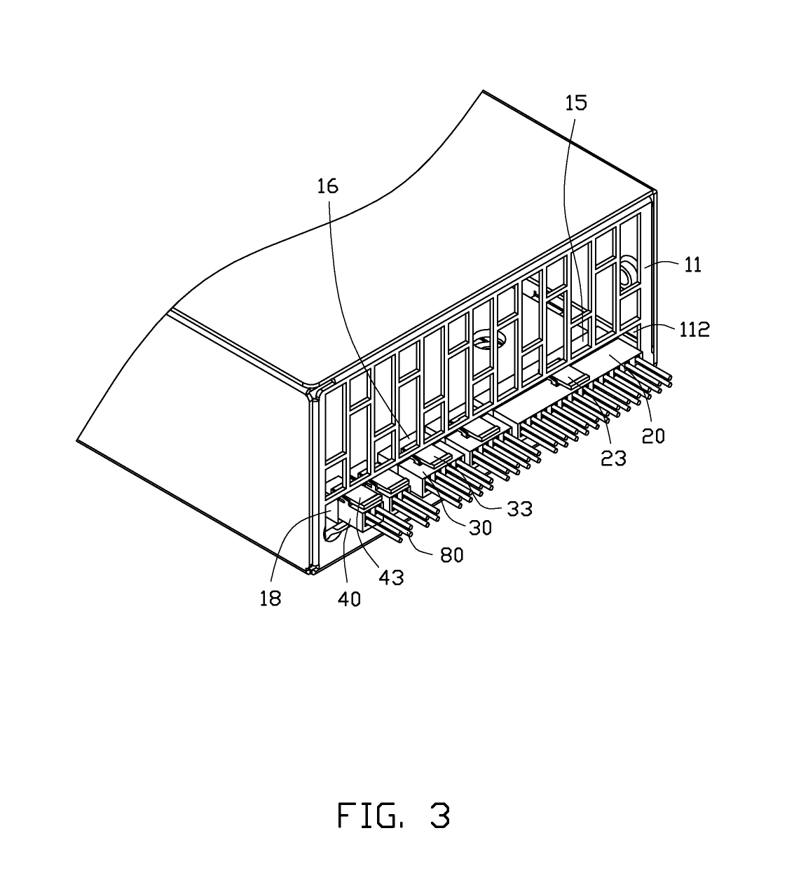

Referring to FIG. 3, the enclosure 10 defines an opening 112 in a lower portion of a front plate 11 of the enclosure 10. The circuit board 12 is mounted with a first power interface 15, two second power interfaces 16, and two third power interfaces 18 all arranged in a row along an edge and adjacent to the opening 112, to output the converted DC powers respectively.

The first power interface 15 includes twenty-four pins 151 extending down from a bottom of the first power interface 15 and electrically welded to the circuit board 12, and twenty-four pins 152 extending forward from a front side of the first power interface 15 and electrically connected to the pins 151 respectively. A hooking slot 153 is defined in a top surface of the first power interface 15, adjacent to the pins 152.

Each second power interface 16 includes eight pins 161 extending down from a bottom of the second power interface 16 and electrically welded to the circuit board 12, and eight pins 162 extending forward from a front side of the second power interface 16 and electrically connected to the pins 161 respectively. A hooking slot 163 is defined in a top surface of the second power interface 16, adjacent to the pins 162.

Each third power interface 18 includes four pins 181 extending down from a bottom of the third power interface 18 and electrically welded to the circuit board 12, and four pins 182 extending forward from a front side of the third power interface 18 and electrically connected to the pins 181 respectively. A hooking slot 183 is defined in a top surface of the third power interface 18, adjacent to the pins 182.

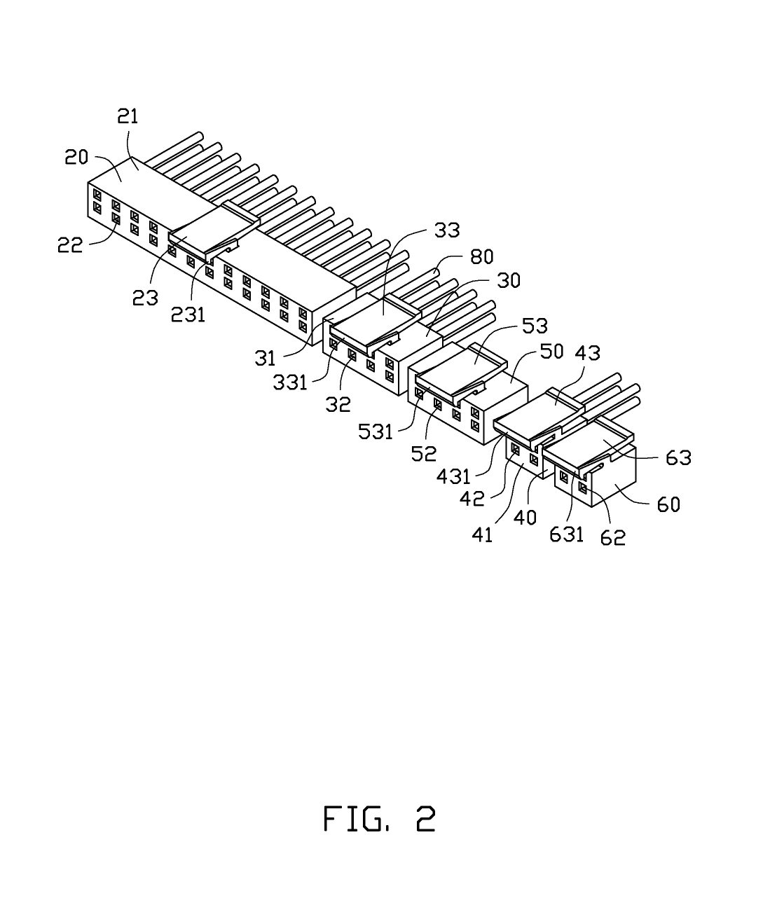

Referring to FIG. 2, the first power cable 20 includes a first plug 21. The first plug 21 defines twenty-four through slots 22 extending through front and rear sides of the first plug 21. Twenty-four wires 80 are respectively extended into the through slots 22 from the front side of the first plug 21 and are electrically connected to terminals located in the through slots 22. A substantially L-shaped hook 23 is formed on a top of the first plug 21, extending to the back and then down. The hook 23 includes a hooking portion 231 at a distal end of the hook 23.

Each second power cable 30 includes a second plug 31. The second plug 31 defines eight through slots 32 extending through front and rear sides of the second plug 31. Eight wires 80 are respectively extended into the through slots 32 from the front side of the second plug 31 and being electrically connected to terminals located in the through slots 32. A substantially L-shaped hook 33 is formed on a top of the second plug 31, extending to the back and then down. The hook 33 includes a hooking portion 331 at a distal end of the hook 33.

Each third power cable 40 includes a third plug 41. The third plug 41 defines four through slots 42 extending through front and rear sides of the third plug 41. Four wires 80 are respectively extended into the through slots 42 from the front side of the third connector and being electrically connected to terminals located in the through slots 42. A substantially L-shaped hook 43 is formed on a top of the third plug 41, extending to the back and then down. The hook 43 includes a hooking portion 431 at a distal end of the hook 43.

The first foolproof member 50 defines eight engaging holes 52 in a rear side. A substantially L-shaped hook 53 is formed on a top of the first foolproof member 50, extending to the back and then down. The hook 53 includes a hooking portion 531 at a distal end of the hook 53.

The second foolproof member 60 defines four engaging holes 62 in a rear side. A substantially L-shaped hook 63 is formed on a top of the second foolproof member 60, extending to the back and then down. The hook 63 includes a hooking portion 631 at a distal end of the hook 63.

If the number of the CPUs 3 is two, and the number of the HDDs 4 is great, the assembly of the power supply unit is as follows; the first plug 21 is extended through the opening 112, to be connected to the first power interface 15, with the pins 152 engaging in the through slots 22, and the hooking portion 231 engaging in the hooking slot 153. The second plugs 31 extend through the opening 112, to be connected to the second power interfaces 16, with the pins 162 of each second power interface 16 engaging in the through slots 32 of the corresponding second plug 31, and the hooking portion 331 engaging in the corresponding hooking slot 163. The third plugs 41 are extended through the opening 112, to be connected to the third power interfaces 18, with the pins 182 of each third power interface 18 engaging in the through slots 42 of the corresponding third plug 41, and the hooking portion 431 engaging in the corresponding hooking slot 183. The terminals in the first plug 21, the second plugs 31, and the third plugs 41 are electrically connected to the pins 152, 162, and 182, respectively. The first power cable 20 is connected to the motherboard 2 to supply corresponding DC power for the motherboard 2. The second power cables 30 are respectively connected to the CPUs 3 to supply corresponding DC powers for the CPUs 3. The third power cables 40 are connected to the HDDs 4 to supply corresponding DC powers for the HDDs 4.

When the relative positions of the electronic components change, for example, the distance from the motherboard 2 to the power supply unit is longer, the first plug 21 of the first power cable 20 is unplugged from the first power interface 15. The first plug 21 of another first power cable 20 with a longer length is plugged into the first power interface 15.

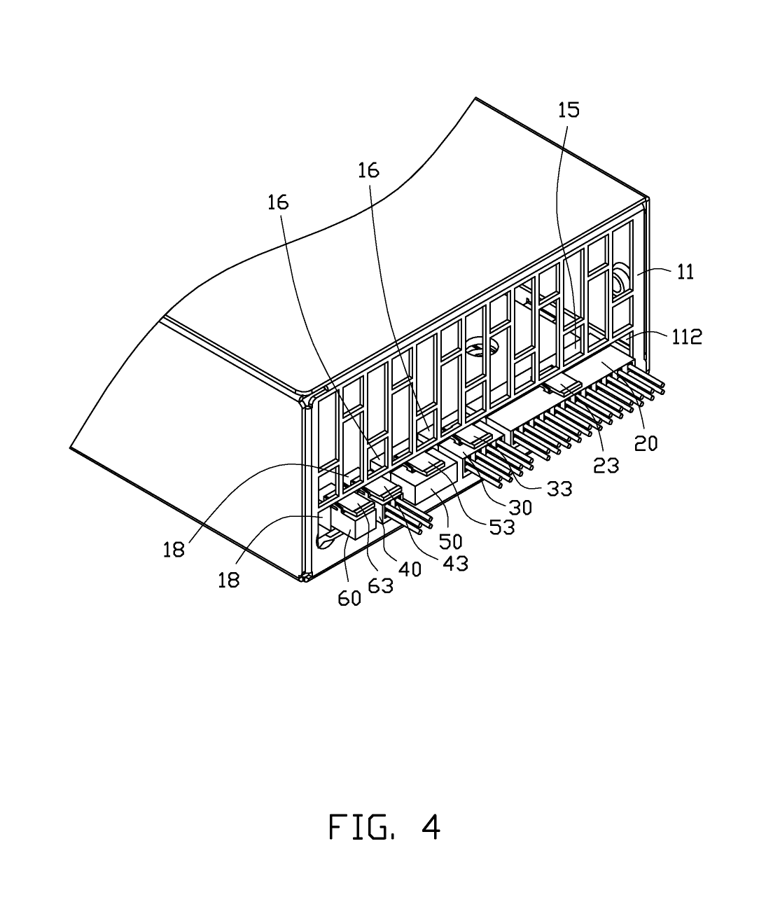

FIG. 4 shows that when there is only one CPU 3, only one of the second plugs 31 is plugged in one of the second power interfaces 16. The first foolproof member 50 is mounted to the other second power interface 16, that is, the first foolproof member 50 is manipulated towards the other second power interface 16 and extended through the opening 112. The pins 162 of the other second power interface 16 are respectively inserted into the engaging holes 52, and the hooking portion 531 engages in the corresponding hooking slot 163. The first foolproof member 50 prevents the pins 162 of the corresponding second power interface 16 from being damaged.

When there is relative few HDDs 4, only one of the third plugs 41 is plugged into one of the third power interfaces 18. The second foolproof member 60 is mounted to the other third power interface 18, that is, the second foolproof member 60 is manipulated towards the other third power interface 18 and extended through the opening 112. The pins 182 of the other third power interface 18 are respectively inserted into the engaging holes 62, and the hooking portion 631 engages in the corresponding hooking slot 183. The second foolproof member 60 prevents the pins 182 of the corresponding third power interface 18 from being damaged.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A power supply unit, comprising:
an enclosure defining an opening in an end of the enclosure;
a circuit board mounted in the enclosure to convert commercial power into a direct current (DC) power;
a power interface electrically connected to the circuit board, near the opening to output the DC power, the power interface comprising a plurality of first pins facing the opening; and
a cable power comprising a plug at an end of the cable power;
wherein the first pins of the power interface are detachably plugged in the plug.

2. The power supply unit of claim 1, wherein a plurality of second pins extends down from a bottom of the power interface and electrically connected to the first pins respectively, the second pins are electrically welded to the circuit board.

3. The power supply unit of claim 1, wherein a hooking slot is defined in the power interface, a substantially L-shaped hook is formed on the plug to engage in the hooking slot.

4. The power supply unit of claim 1, wherein the plug defines a plurality of through slots, a plurality of wires is respectively extended into first ends of the through slots away from the power interface, the first pins are inserted into second ends of the through slots opposite to the first ends and electrically connected to the wires.

5. A power supply unit, comprising:
an enclosure defining an opening in an end of the enclosure;
a circuit board mounted in the enclosure to convert commercial power into two direct current (DC) powers;
two power interfaces electrically connected to the circuit board, near the opening to output the DC powers respectively, a plurality of first pins formed on each power interface and facing the opening;
a foolproof member; and
a power cable comprising a plug at an end of the power cable;
wherein the first pins of one of the power interfaces are detachably plugged in the plug or the foolproof member, the first pins of the other power interface are detachably engage in the foolproof member or the plug.

6. The power supply unit of claim 5, wherein a plurality of second pins extends down from a bottom of each power interface and electrically connected to the first pins of the power interface respectively, the second pins are electrically welded to the circuit board.

7. The power supply unit of claim 5, wherein a hooking slot is defined in each power interface, a substantially L-shaped hook is formed on the plug to engage in the corresponding hooking slot, a substantially L-shaped hook is formed on the foolproof member to engage in the corresponding hooking slot.

8. The power supply unit of claim 5, wherein the plug defines a plurality of through slots, a plurality of wires is extended into first ends of the through slots away from the power interfaces, the first pins of the corresponding power interface are inserted in second ends of the through slots opposite to the first ends and electrically connected to the wires respectively.

9. A power supply unit, comprising:
an enclosure defining an opening in an end of the enclosure;
a circuit board mounted in the enclosure to convert commercial power into several direct current (DC) powers with different voltages;
a plurality of power interfaces of different types electrically connected to the circuit board and near the opening, to output the DC powers respectively, a plurality of first pins formed on each power interface and facing the opening, the power interfaces of different types having different numbers of first pins; and
a plurality of power cables each comprising a plug at an end of the power cable and corresponding to one of the types of the power interfaces;
wherein the first pins of each power interface are detachably plugged in the plug of the corresponding type of power cable.

10. The power supply unit of claim 9, wherein a plurality of second pins extends down from a bottom of each power interface and electrically connected to the first pins of the power interface respectively, the second pins are electrically welded to the circuit board.

11. The power supply unit of claim 9, wherein a hooking slot is defined in each power interface, a substantially L-shaped hook is formed on each plug to engage in the corresponding hooking slot.

12. The power supply unit of claim 9, wherein each plug defines a plurality of through slots, a plurality of wires is extended into first ends of the through slots of each plug away from the power interfaces, the number of the through slots of each plug is the same as the first pins of the corresponding type of the power interface, the first pins of each power interface are inserted in second ends of the through slots of the corresponding plug and electrically connected to the corresponding wires.

13. The power supply unit of claim 9, further comprising a plurality of foolproof members with different types, wherein a plurality of engaging holes is defined in each foolproof member, the number of the engaging holes of each type of the foolproof members is the same as the number of the first pins of the corresponding type of the power interfaces, the first pins of each power interface are detachably inserted in the engaging holes of the corresponding foolproof member.

14. The power supply unit of claim 13, wherein a hooking slot is defined in each power interface, a substantially L-shaped hook is formed on each foolproof member to engage in the hooking slot of the corresponding plug.
